(19) United States
(12) Patent Application Publication
(10) Pub. No.: US 2013/0320816 A1
(43) Pub. Date: Dec. 5, 2013

(54) VIBRATOR ELEMENT, ELECTRONIC DEVICE, ELECTRONIC APPARATUS, AND METHOD OF MANUFACTURING VIBRATOR ELEMENT

(71) Applicant: Seiko Epson Corporation, Tokyo (JP)

(72) Inventors: Keiichi Yamaguchi, Ina (JP); Osamu Kawauchi, Shiojiri (JP)

(73) Assignee: Seiko Epson Corporation, Tokyo (JP)

(21) Appl. No.: 13/904,405

(22) Filed: May 29, 2013

(30) Foreign Application Priority Data
May 31, 2012 (JP) 2012-124137

(51) Int. Cl. H01L 41/332; H01L 41/04

(52) U.S. Cl. CPC H01L 41/332; H01L 41/04
USPC 310/367; 216/13

(57) ABSTRACT

A vibrator element includes a base section, and a vibrating arm projecting from the base section, and having a plurality of groove sections, the vibrating arm is provided with the groove sections, and the groove sections are each formed to have a length in a width direction of the vibrating arm longer than a length in a longitudinal direction of the vibrating arm, and arranged side by side along the longitudinal direction of the vibrating arm.

### BACKGROUND

1. Technical Field

The present invention relates in particular to a vibrator element having a vibrating arm provided with a groove section, an electronic device, an electronic apparatus, and a method of manufacturing a vibrator element.

2. Related Art

A tuning-fork piezoelectric vibrator element as an example of the vibrator element has a base section and two vibrating arms formed so as to project from the base section. The vibrating arms are each provided with groove sections, and the groove sections are provided to both sides of the vibrating arm. Therefore, the vibrating arm is formed to have a roughly H-shaped cross-sectional shape. Such a tuning-fork piezoelectric vibrator element can provide an excellent vibration performance such as an improved electric field efficiency, a low vibration loss of the vibrating arms, or a CI value suppressed to a low level, and further, the overall shape of the vibrator element can be miniaturized.

As some known examples of such a vibrator element, there can be cited JP-A-2002-76806 (Document 1), JP-A-2004-200915 (Document 2), and Japanese Patent No. 4,636,170 (Document 3).

In the method of manufacturing a vibrator element disclosed in Document 1, metal masks are firstly formed respectively on an obverse surface and a reverse surface of a quartz crystal wafer, then photoresist films are formed respectively on the metal masks, and then the photoresist films are patterned. Then, the metal masks are patterned with the patterns of the respective photoresist films. The patterns are designed so as to fit the contour of the vibrator element. Then, photoresist films are deposited on the respective metal mask patterns, and then the photoresist films are patterned. The patterns of the photoresist films are designed in accordance with patterns of grooves of the vibrator element. Then, the quartz crystal wafer is etched in accordance with the patterns of the metal masks to thereby form the contour of the vibrator element. Then, the metal masks are patterned in accordance with the groove patterns, and then the grooves are provided to the vibrator element by etching.

However, according to the manufacturing method of Document 1, since the process of forming the outer shape of the vibrator element and the process of forming the groove sections are performed separately from each other, it is required to perform the two-staged deposition of the photoresist films respectively on the contour and the groove sections. When depositing the photoresist films on the metal masks in the latter process, the patterning is performed in accordance with the groove patterns of the metal masks, and there is a problem that it is difficult to accurately align the grooves to the contour, which has already been formed. In the case in which the grooves fail to be formed at the designed positions, the balance of the vibrating arms becomes poor, and the vibration becomes unstable. Therefore, the stability of the frequency is degraded, and the resonant frequency of the vibrator element is shifted from the design value.

Therefore, in the case of the vibrator element disclosed in Document 2, the outer shape of the vibrator element and the groove sections are patterned at the same time, and then the outline etching and the etching of the grooves are performed simultaneously, and thus the number of the manufacturing processes is decreased. Further, due to the anisotropy of the quartz crystal in the etching process, the groove width of the grooves is set to a level within the projection amount of the modified shape formed in the vibrating arms.

Further, in the case of the vibrator element disclosed in Document 3, the outer shape of the vibrator element and the groove sections are patterned at the same time, and then the outline etching and the etching of the grooves are performed simultaneously, and thus the number of the manufacturing processes is decreased similarly to the case of Document 2. Further, in the groove section of the vibrating arms, a plurality of small grooves each sectioned in the width direction of the vibrating arms, and each elongated in the longitudinal direction is formed so as to be arranged in parallel to each other along the longitudinal direction of each of the vibrating arms.

When forming the outer shape of the vibrator element and the groove sections, the etching process may take longtime in some cases depending on the type of the vibrator element. FIG. 8 is an explanatory diagram of an etching process of the groove section of the vibrator element of the related art. As shown in the drawing, in the case of the configuration of the groove section 2 having a shape elongated in the longitudinal direction of the vibrating arm 1, in the case in which the etching process takes only short time, etching proceeds along the outline pattern of the groove section 2 elongated in the longitudinal direction as indicated by a dotted line A in the drawing. In contrast, in the case in which the etching process takes long time, etching of either one 3a of the sidewalls of the groove section 2 elongated in the longitudinal direction proceeds more than etching of the other 3b of the sidewalls due to the anisotropy of the quartz crystal as indicated by a dashed-dotted line B in the drawing. The groove section 2a to be generated becomes asymmetric about the center of the vibrating arm 1, and has a non-uniformly deformed shape with the distances a, b from the side surfaces of the vibrating arm 1 to the sidewalls of the groove section different from each other. Thus, there is a problem that the balance of the vibrating arm 1 is poor, and the vibration becomes unstable.

### SUMMARY

An advantage of some aspects of the invention is to provide a vibrator element, an electronic device, an electronic apparatus, and a method of manufacturing a vibrator element, with which the manufacturing process can be simplified by performing the outline etching and the etching of the groove sections at the same time when manufacturing the vibrator element to thereby improve the relative positional accuracy between the groove sections and the outer shape.

The invention can be implemented as the following forms or application examples.

### Application Example 1

This application example of the invention is directed to a vibrator element including a base section, and a vibrating arm projecting from the base section, and having a plurality of groove sections, and the groove sections are each formed to have a length in a width direction of the vibrating arm longer than a length in a longitudinal direction of the vibrating arm, and arranged side by side along the longitudinal direction of the vibrating arm.

According to the configuration described above, since the groove sections of the vibrating arms can be formed to have an elongated shape with the length in the width direction set to be longer than the length in the longitudinal direction of the vibrating arm, and the groove sections are never processed so deep as to penetrate the substrate due to the fin-like modified shape in the X, Y directions caused by the anisotropy of quartz crystal even with the long-lasting etching process, the relative positional accuracy between the outer shape of the vibrating arm and the groove sections can be improved. Therefore, the vibrator element superior in vibration characteristics can be obtained.

### Application Example 2

The vibrator element according to the application example described above may be configured such that each of the groove sections has a polygonal shape in a plan view of the vibrating arm.

According to the configuration described above, since the polygonal groove sections each having an elongated shape with the length in the width direction set to be longer than the length in the longitudinal direction of the vibrating arm can be formed, and the groove sections are never processed so deep as to penetrate the substrate due to the fin-like modified shape in the X, Y directions caused by the anisotropy of quartz crystal even with the long-lasting etching process, the relative positional accuracy between the outer shape of the vibrating arm and the groove sections can be improved. Therefore, the vibrator element superior in vibration characteristics can be obtained.

### Application Example 3

The vibrator element according to the application example described above may be configured such that a corner portion of each of the groove sections includes a curved shape in a plan view of the vibrating arm.

### Application Example 4

The vibrator element according to the application example described above may be configured such that the base section and the vibrating arm are formed of piezoelectric single crystal.

According to the configuration described above, a vibrator element with a stable resonant frequency without being affected by a change in ambient temperature can be obtained.

### Application Example 5

The vibrator element according to the application example described above may be configured such that the groove sections are formed on one principal surface and the other principal surface of the vibrating arm.

According to the configuration described above, a vibrator element having the groove sections formed to have accurate relative positions with the contour disposed on one principal surface and the other principal surface can be obtained.

### Application Example 6

This application example of the invention is directed to an electronic device including any of the vibrator elements described above.

According to the configuration described above, an electronic device equipped with the vibrator element provided with the function described above can be obtained.

### Application Example 7

This application example of the invention is directed to an electronic apparatus including any of the vibrator elements described above.

According to the configuration described above, an electronic apparatus equipped with the vibrator element provided with the function described above can be obtained.

### Application Example 8

This application example of the invention is directed to a method of manufacturing a vibrator element having a base section, and a vibrating arm formed so as to project from the base section and provided with a plurality of groove sections. The method includes: providing an outline pattern of the vibrator element and a pattern corresponding to the groove sections each formed to have a length in a width direction of the vibrating arm longer than a length in a longitudinal direction of the vibrating arm, and arranged side by side along the longitudinal direction of the vibrating arm simultaneously to a photoresist film on a metal film formed on a substrate, removing the photoresist film and the metal film from an area corresponding to an outer shape of the vibrator element and areas corresponding to the groove sections, and forming simultaneously the outer shape of the vibrator element and the groove sections by etching the substrate.

According to this method, since the groove sections are never processed so deep as to penetrate the substrate due to the fin-like modified shape in the X, Y directions caused by the anisotropy of quartz crystal even with the long-lasting etching process, the relative positional accuracy between the outer shape of the vibrating arm and the groove sections can be improved. Therefore, the vibrator element superior in vibration characteristics can be manufactured.

### BRIEF DESCRIPTION OF THE DRAWINGS

The invention will be described with reference to the accompanying drawings, wherein like numbers reference like elements.

FIG. 1 is a perspective view of a vibrator element according to an embodiment of the invention.

FIG. 2 is an enlarged plan view of a part of a vibrating arm.

FIG. 3 is an explanatory diagram of groove sections of a first modified example.

FIG. 4 is an explanatory diagram of groove sections of a second modified example.

FIGS. 5A through 5D are schematic cross-sectional views showing manufacturing process of the vibrator element according to the present embodiment in sequence.

FIGS. 6A and 6B are schematic cross-sectional views showing manufacturing process of the vibrator element according to the present embodiment in sequence.

FIG. 7 is an explanatory diagram of an electronic apparatus using the vibrator element according to the embodiment of the invention.

FIG. 8 is an explanatory diagram of an etching process of the groove section of the vibrator element of the related art.

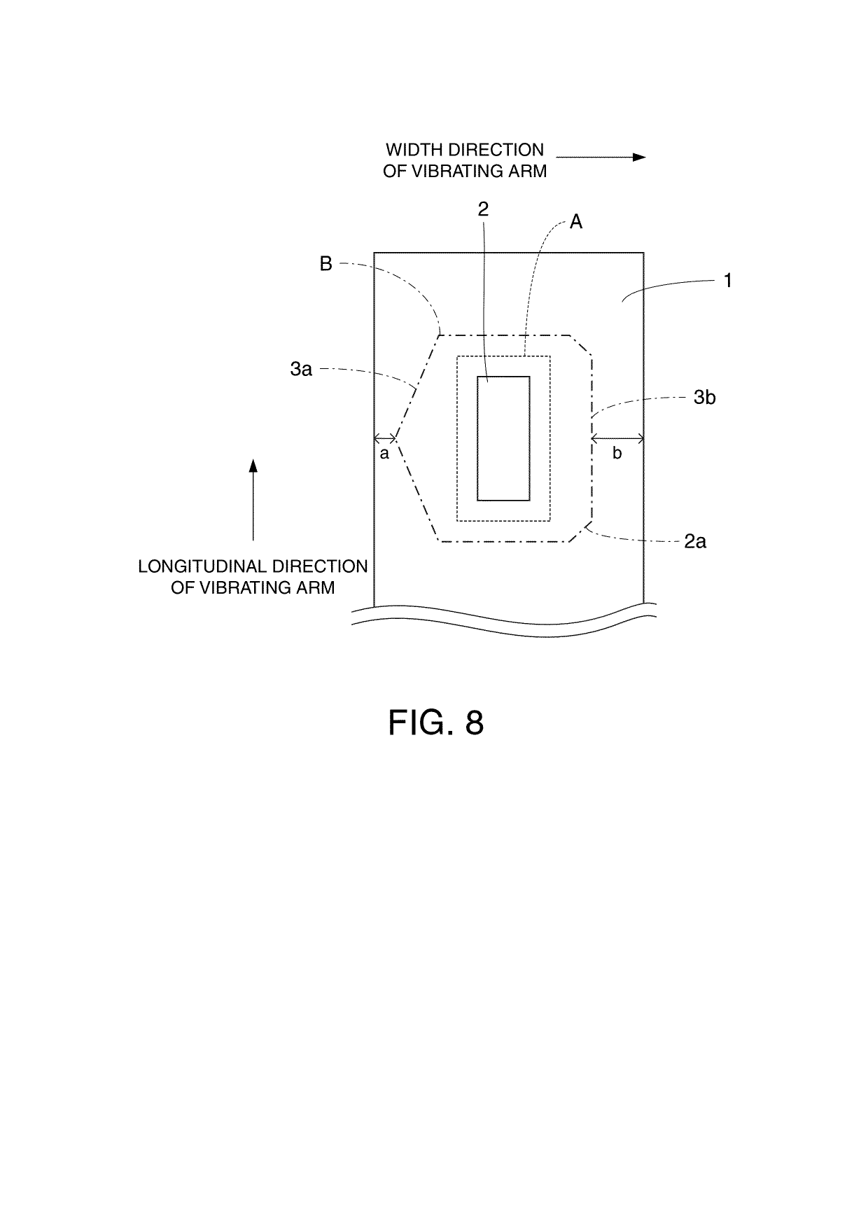

### DESCRIPTION OF AN EXEMPLARY EMBODIMENT

Hereinafter, a vibrator element, an electronic device, an electronic apparatus, and a method of manufacturing the vibrator element according to an embodiment of the invention will be explained in detail with reference to the accompanying drawings.

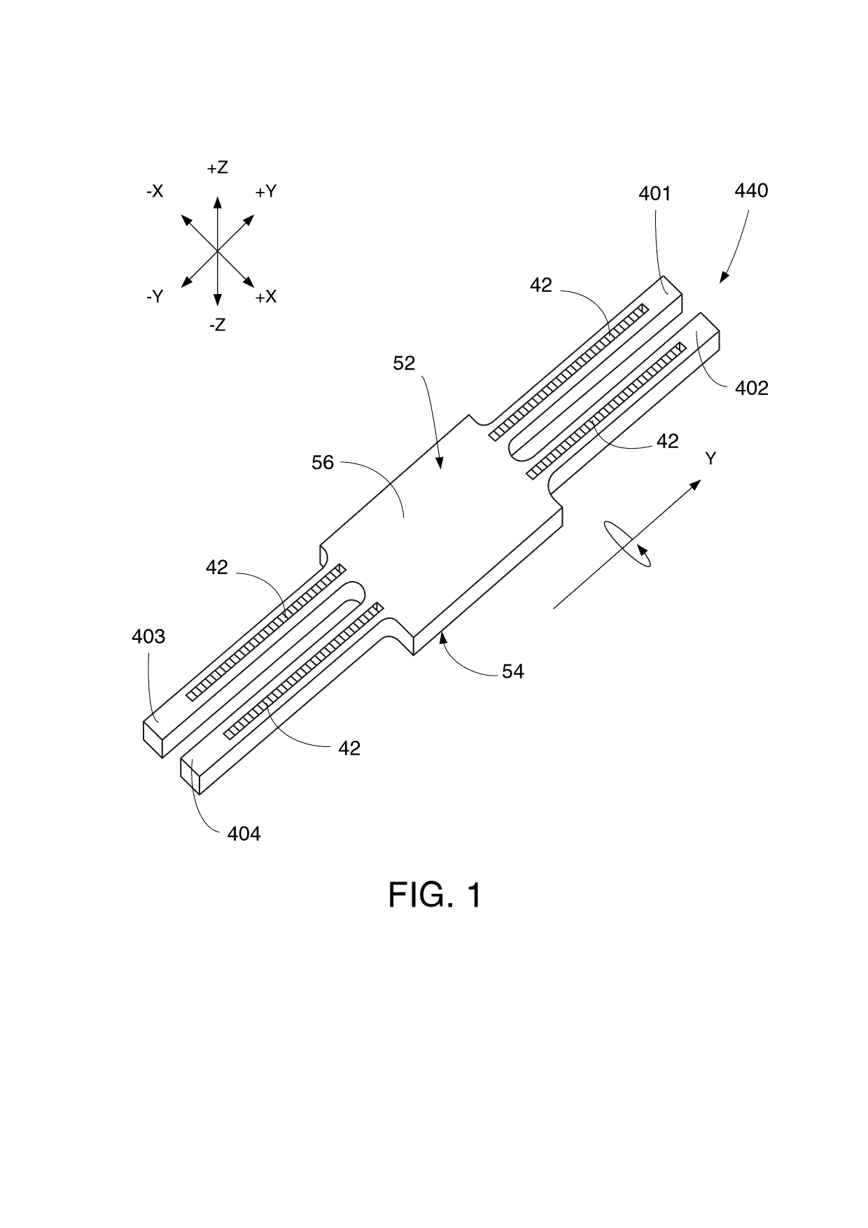

FIG. 1 is a perspective view of the vibrator element according to the embodiment of the invention. As shown in the drawing, the vibrator element 440 has a first principal surface 52 and a second principal surface 54 extending in a plane including an X axis (a second axis) and a Y axis (a first axis) perpendicular to the X axis in the same plane, and being in an obverse-reverse relationship with each other. It should be noted that an axis perpendicular to the first principal surface 52 and the second principal surface 54 is defined as a Z axis. The vibrator element 440 has a first vibrating arm 401 and a second vibrating arm 402 extending in a +Y-axis direction from a base section 56, and a third vibrating arm 403 and a fourth vibrating arm 404 extending therefrom in a −Y-axis direction. The base section 56, the first vibrating arm 401, and the second vibrating arm 402 constitute a tuning-fork vibrator element, and the base section 56, the third vibrating arm 403, and the fourth vibrating arm 404 constitute a tuning-fork vibrator element. The vibrator element 440 having a configuration in which two such tuning-fork vibrator elements are bonded to the base section 56, and the extending directions of the vibrating arms of the two tuning-fork vibrator elements are opposite to each other is called an H-type vibrator element.

The first vibrating arm 401 and the second vibrating arm 402 are configured to be parallel to each other, and to have the same length and the same cross-sectional shape, and the third vibrating arm 403 and the fourth vibrating arm 404 are configured to be parallel to each other, and to have the same length and the same cross-sectional shape. In the vibrator element 440 according to the present embodiment, the first vibrating arm 401 and the second vibrating arm 402 constitute the drive arms (the excitation arms), and the third vibrating arm 403 and the fourth vibrating arm 404 constitute the detection arms. In each of the first through fourth vibrating arms 401, 402, 403, and 404, a plurality of groove sections 42, each of which has an elongated shape longer in the width direction than in the length direction of the vibrating arm, is formed on each of the first principal surface 52 and the second principal surface 54 along the longitudinal direction of the vibrating arm.

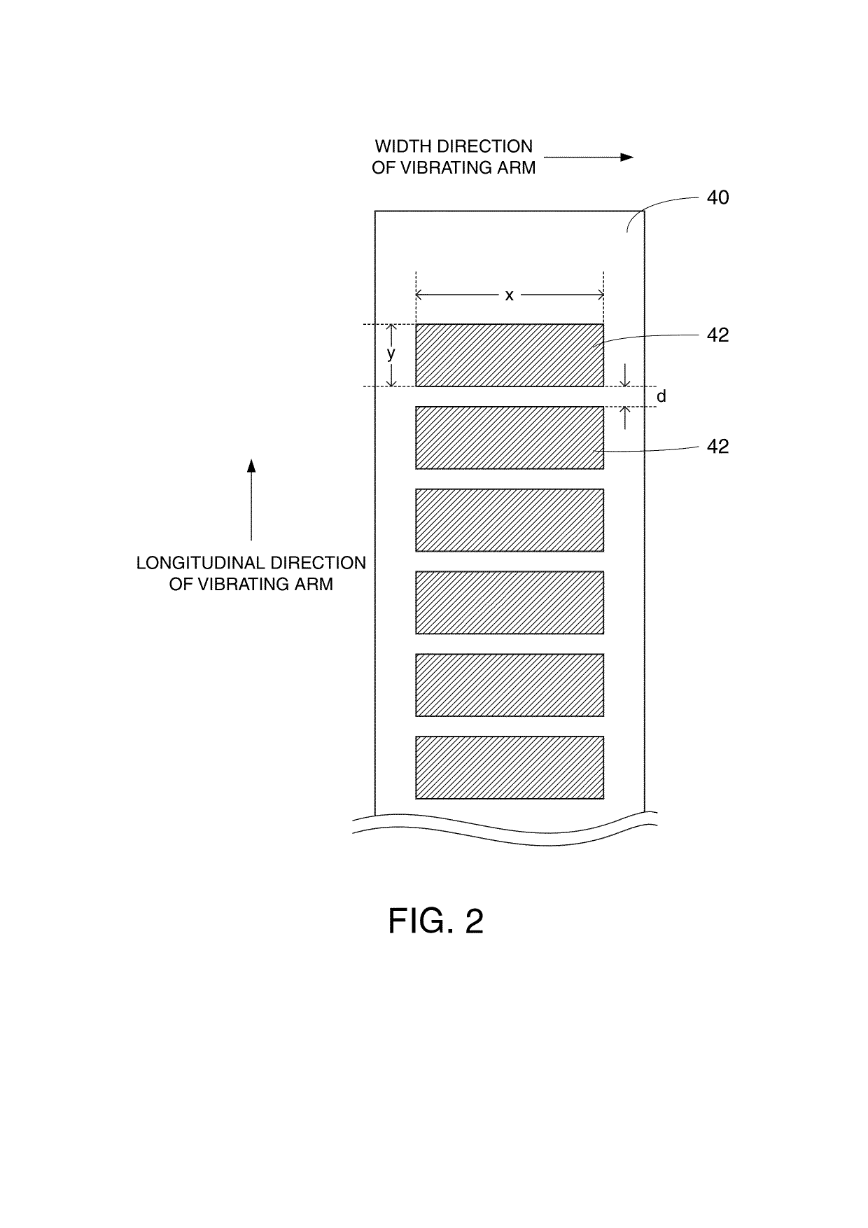

FIG. 2 is an enlarged plan view of a part of the vibrating arm. As shown in the drawing, a plurality of the groove sections 42 is formed side by side along the longitudinal direction of the vibrating arm 40. Each of the groove sections 42 is formed on one principal surface, the other principal surface, or both of the principal surfaces of the vibrating arm 40. The groove sections 42 are each formed to have an elongated shape with the length x in the width direction of the vibrating arm 40 longer than the length y in the longitudinal direction, in other words x>y. Further, the groove sections 42 are arranged in parallel to each other with a predetermined gap d disposed therebetween so that the respective sidewalls do not have contact with each other. Although the groove sections 42 shown in FIG. 2 are arranged side by side in a line along the longitudinal direction of the vibrating arm 40, it is also possible to arrange the columns, each of which has a plurality of groove sections 42 arranged in the width direction, side by side in the longitudinal direction in the case in which the width dimension of the vibrating arm 40 is large. It should be noted in this case that the groove sections 42 in each of the columns are arranged with a predetermined gap disposed therebetween so that the respective sidewalls located in the longitudinal direction of the groove sections 42 do not have contact with each other. Such groove sections 42 are partitioned by a grid-like frame, and arranged side by side along the longitudinal direction. Further, a plurality of crystal faces each having a fin-like modified shape in the XY direction caused by the anisotropy of the quartz crystal is formed inside the groove section 42, and a slope of gradually increasing the depth toward the rough center is provided. Thus, the groove sections 42 are prevented from being processed to penetrate the substrate even if the etching process is performed for a long period of time. Inside each of the groove sections 42, there is formed an excitation electrode (not shown). The vibrator element having such a configuration can generate a flexural vibration of the vibrating arms by generating the electric field in the quartz crystal material sandwiched between the excitation electrodes using an external voltage applied via extraction electrodes (not shown).

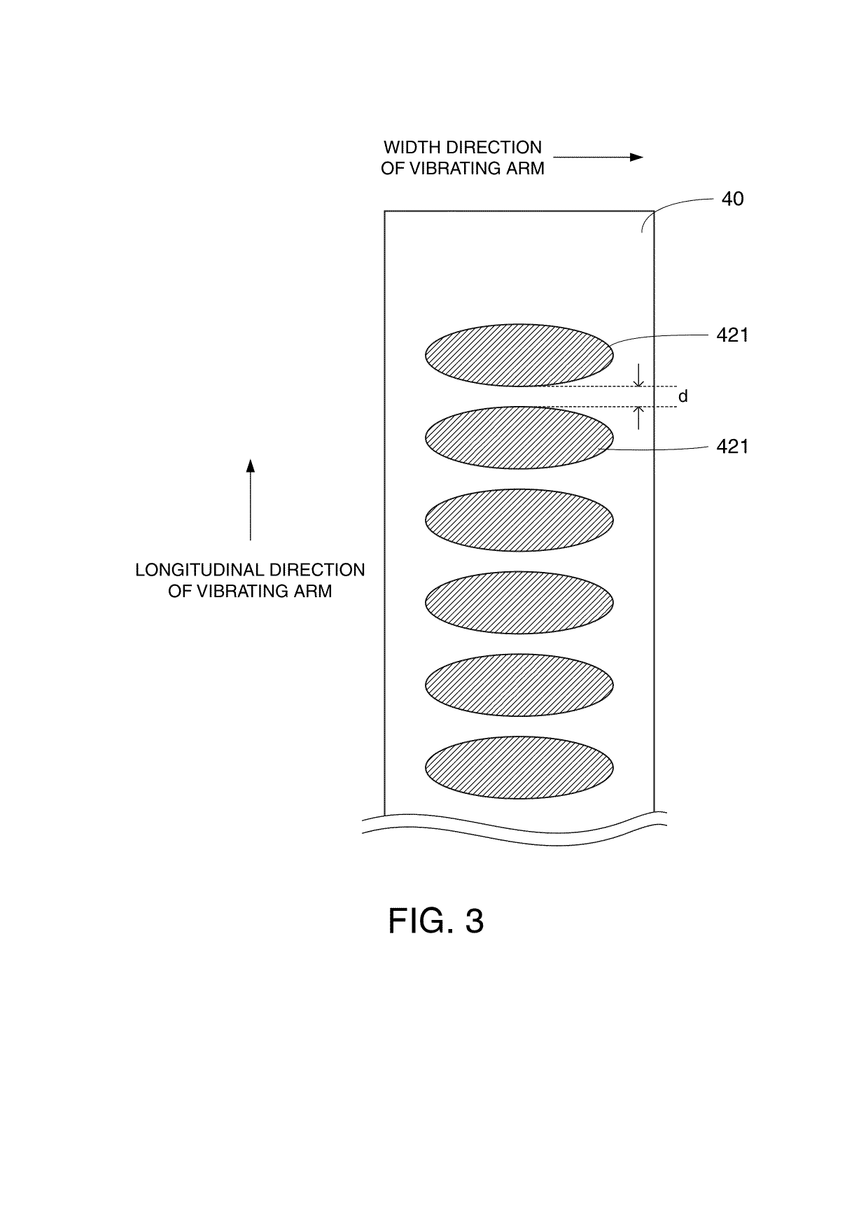

FIG. 3 is an explanatory diagram of groove sections of a first modified example. As shown in the drawing, the groove sections 421 of the first modified example are each formed to have an elliptical shape with a length in the width direction longer than a length in the longitudinal direction of the vibrating arm 40 in the plan view of the vibrating arm 40. In other words, the corner portions of each of the groove sections include a curved shape. Further, the groove sections 421 having the elliptical shape are arranged in parallel to each other along the longitudinal direction with a predetermined gap d disposed therebetween so that the respective sidewalls do not have contact with each other.

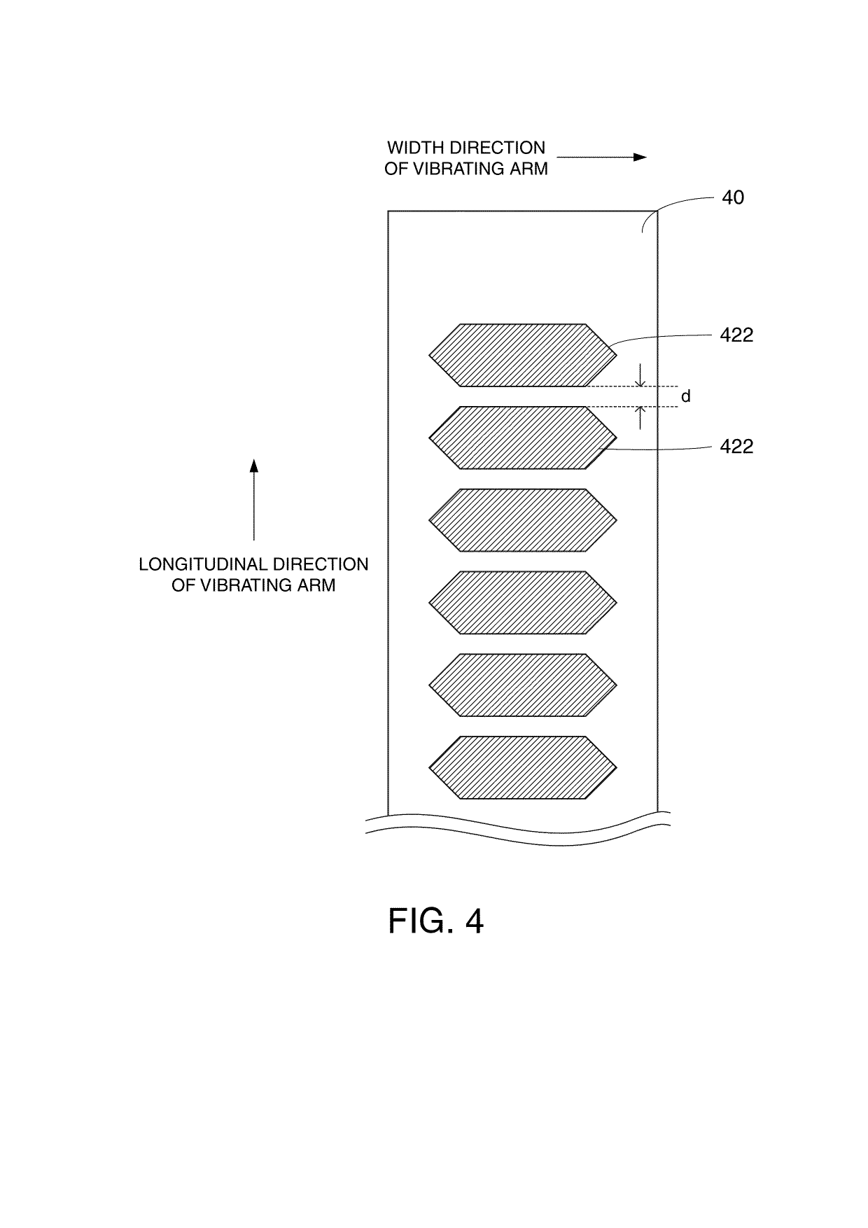

FIG. 4 is an explanatory diagram of groove sections of a second modified example. As shown in the drawing, the groove sections 422 of the second modified example are each formed to have a hexagonal shape with a length in the width direction longer than a length in the longitudinal direction of the vibrating arm 40 in the plan view of the vibrating arm 40. Besides the above, the groove sections 422 can also be formed to have a polygonal shape such as a rhombic shape or an octagonal shape. Further, the groove sections 422 having the hexagonal shape are arranged in parallel to each other along the longitudinal direction with a predetermined gap d disposed therebetween so that the respective sidewalls do not have contact with each other.

In the vibrator element 440 having such a configuration, when an excitation signal is input to the electrodes (not shown), the first vibrating arm 401 and the second vibrating arm 402 vibrate in a flexural mode in ±X axis directions. On this occasion, in the case of rotating the vibrator element 440 around the Y axis (the detection axis), the Coriolis force generates in a direction perpendicular to the vibration direction (an in-plane vibration) of the first vibrating arm 401 and the second vibrating arm 402, and the third vibrating arm 403 (the detection arm) and the fourth vibrating arm 404 (the detection arm) vibrate in ±Z directions in an out-of-plane vibration mode. By measuring the charge amount generated by the out-of-plane vibration, the angular velocity acting on the vibrator element 440 can be detected.

It should be noted that the vibrator element according to the embodiment of the invention can also be applied to the configuration having the vibrating arm provided with a groove section such as a tuning-fork piezoelectric vibrator element or a tuning-fork piezoelectric vibrator element for a gyroscope, besides the H-type vibrator element described above.

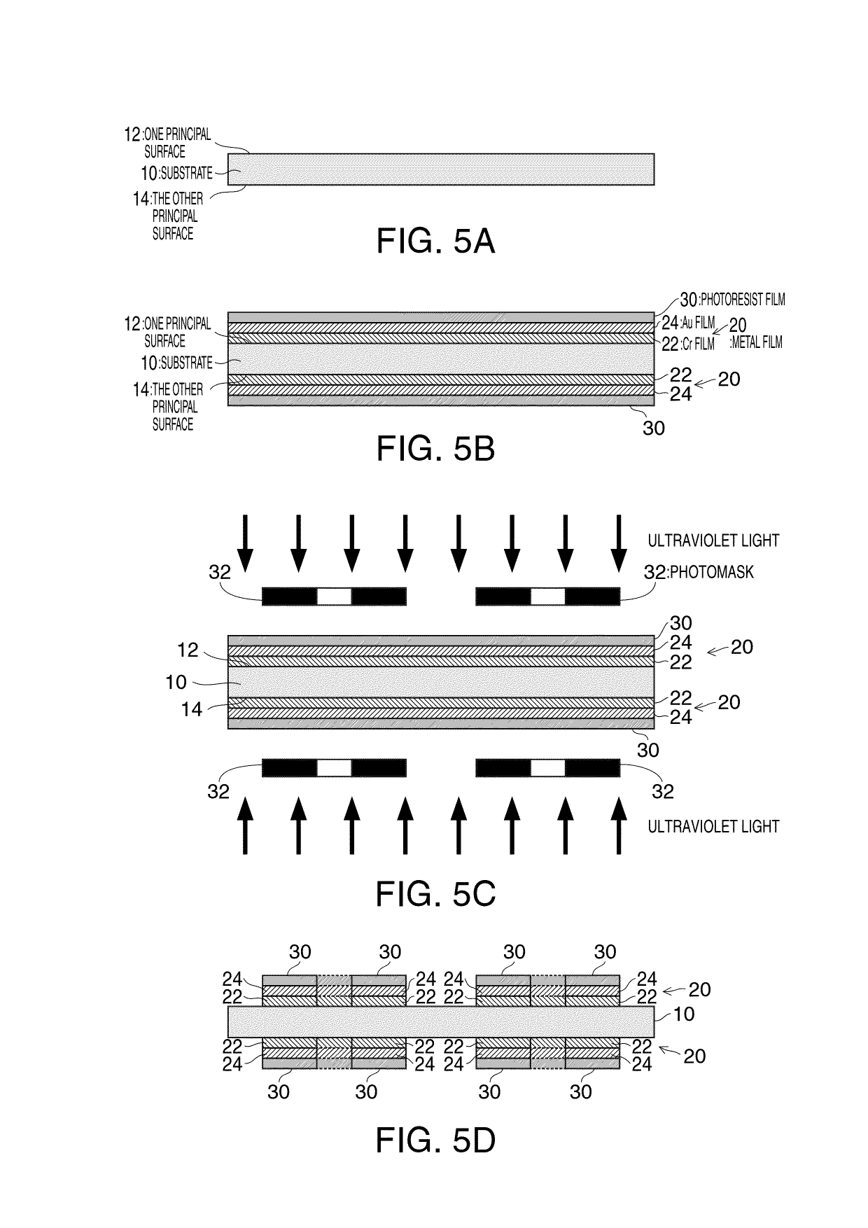

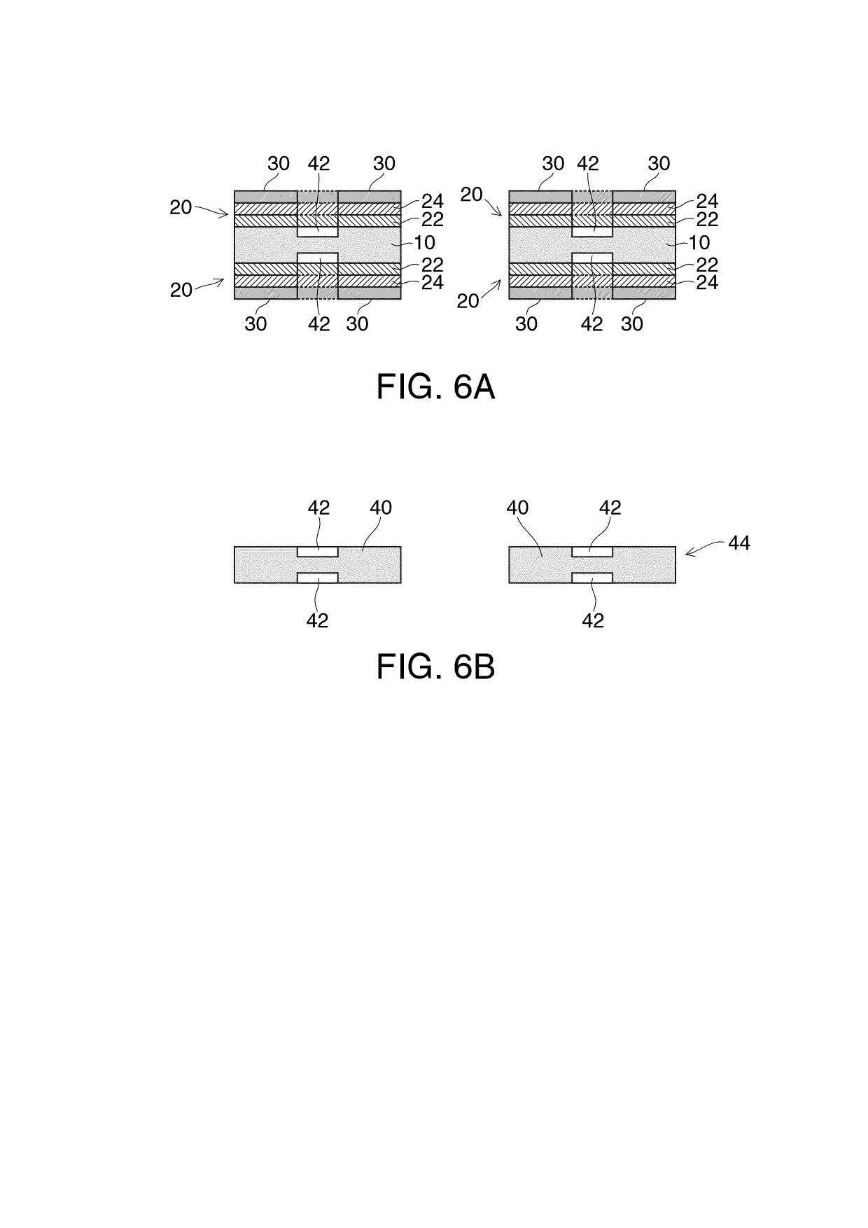

Then, a method of manufacturing the vibrator element with the configuration described above will hereinafter be explained. FIGS. 5A through 5D, 6A, and 6B are schematic cross-sectional views showing manufacturing process of the vibrator element according to the present embodiment in sequence.

Firstly, such a substrate 10 as shown in FIG. 5A is prepared. The substrate 10 is a plate-like (wafer-shaped) member ground to have a predetermined thickness, and piezoelectric single crystal is preferably used as the material thereof. As a more specific material of the substrate 10, there can be used piezoelectric single crystal made of quartz crystal, lithium niobate single crystal, lithium tantalate single crystal, lithium niobate-lithium tantalate solid solution single crystal, lithium borate single crystal, langasite single crystal, and so on. By using such piezoelectric single crystal as the substrate 10, a vibrator element with a stable resonant frequency without being affected by a change in ambient temperature can be obtained.

Subsequently, as shown in FIG. 5B, metal films 20 are formed respectively on one principal surface 12 and the other principal surface 14 of the substrate 10. The metal films can be formed using a vapor deposition process or a sputtering process. The metal films 20 is preferably made of a material having corrosion resistance against the etching solution such as hydrofluoric acid of the substrate 10 for forming the outer shape of the vibrator element in the posterior process. In the metal films 20 of the present embodiment, there is adopted, as an example, a laminate structure of two layers (a Cr (chromium) film 22 as a lower layer and an Au (gold) film 24 as an upper layer) obtained by forming the Cr film 22 as the upper layer of the substrate 10 and then stacking the Au film 24 as the upper layer of the Cr film 22. The Cr film 22 is superior in adhesiveness with the substrate 10 such as quartz crystal. On the other hand, the Au film 24 is superior in corrosion resistance against the etching solution of the substrate 10 to the Cr film 22. Besides the above, a laminate structure with Ti (titanium), W (tungsten), and so on combined with each other can also be adopted.

Then, a photoresist is applied on the entire surface of each of the metal films 20, and is then dried to thereby form photoresist films 30 with a predetermined thickness.

Subsequently, as shown in FIG. 5C, photomasks 32 having an etching pattern corresponding to the outer shape of the vibrator element and an etching pattern corresponding to the groove sections drawn are disposed respectively on the photoresist films 30 on the both principal surfaces of the substrate 10. The photomasks 32 are provided with openings for exposing the outline portion of the vibrator element and areas corresponding to the groove sections to ultraviolet light. The portions of the etching patterns of the photomasks 32 corresponding to the groove sections are each formed to have an elongated shape having a length in the width direction of the vibrating arms larger than a length in the longitudinal direction thereof. The rest of the areas corresponding to the inner shape of the vibrator element is arranged to block the ultraviolet light. Then, the exposure to the ultraviolet light is performed to thereby transfer the etching patterns.

In such a method of manufacturing the vibrator element according to the embodiment of the invention as described above, since the outer shape of the vibrator element and the forming positions of the groove sections are patterned at the same time, the accuracy of the relative positions between the outer shape of the vibrator element and the groove sections can be improved compared to the related art method of pattering the outer shape of the vibrator element and the forming positions of the groove sections in separate processes.

Then, as shown in FIG. 5D, the exposed portions of the photoresist films 30 are first developed with a developing solution to be removed, to thereby expose the portions of the metal films 20 corresponding to the outer shape of the vibrator element. Here, the portions of the photoresist films 30 corresponding to the groove sections are also removed to have recessed shapes following the shapes of the groove sections. In contrast, in the places corresponding to the gaps between the groove sections, there remain the photoresist films 30 and the metal films 20.

Then, the portions of the metal films 20 on the substrate 10, on which the photoresist films 30 are no longer formed, are etched with a predetermined etching solution to thereby be removed. The removal of the metal films 20 is performed by removing the Au film 24 in the upper layer, and then removing the Cr film 22 in the lower layer in a stepwise manner. Thus, it results that the portions of the substrate 10 on which the metal films 20 are removed are exposed.

Then, as shown in FIG. 6A, etching of the vibrator element is performed. Specifically, the outer shape and the groove sections 42 are etched simultaneously with the inner shape (the inside of the outer shape except the groove sections) of the vibrator element left alone. As the etching process, wet etching, for example, can be used. The etching process may take long time in some cases depending on the type of the vibrator element. Due to such an etching process performed for a long period of time, the outer shape of the vibrator element is completely etched off. In contrast, since the groove sections 42 are each formed to have an elongated shape having the length in the width direction longer than the length in the longitudinal direction of the vibrator element, a plurality of crystal faces having the fin-like modified shape in the X, Y directions is formed due to the etching anisotropy of quartz crystal. The crystal face is provided with a slope of gradually increasing the groove depth toward the rough center of the groove section 42. Further, since the sidewalls of the groove section 42 along the longitudinal direction of the vibrator arm are shorter than the sidewalls of the groove section 42 along the width direction, the fin-like crystal face due to the anisotropy of quartz crystal is difficult to be formed and the processing amount of the etching is also small in the sidewalls of the groove section 42 along the longitudinal direction compared to the sidewalls of the groove section 42 along the width direction. Therefore, since the groove section is never processed so deep as to penetrate the substrate, the relative positional accuracy between the vibrating arm and the groove sections can be improved. Therefore, the vibrator element superior in vibration characteristics is obtained.

Then, by completely removing the photoresist films and the metal films, the vibrator element 44 provided with the groove sections 42 can be obtained as shown in FIG. 6B.

According to such a vibrator element related to the invention as described above, since the groove sections of the vibrating arms can be formed to have an elongated shape with the length in the width direction set to be longer than the length in the longitudinal direction of the vibrating arms, and the groove sections are never processed so deep as to penetrate the substrate due to the fin-like modified shape in the X, Y directions caused by the anisotropy of quartz crystal even with the long-lasting etching process, the relative positional accuracy between the outer shape of the vibrating arm and the groove sections can be improved. Therefore, the vibrator element superior in vibration characteristics can be obtained.

Further, by performing the outline etching of the vibrator element and the etching of the groove sections simultaneously, it is possible to shorten the manufacturing process to thereby make the manufacturing easy. Further, since the patterning for the outline etching of the vibrator element and the patterning for the etching of the groove sections are performed simultaneously in the same process, there occurs no displacement of the groove sections to the vibrating arm. Therefore, a harmful influence on the vibration performance of the vibrator element can be prevented.

Further, in the case of applying the vibrator element according to the embodiment of the invention to the detecting vibrating arms of an H-type gyro sensor, since the groove sections are each formed to have a shape elongated in the width direction of the vibrating arm, the gaps between the groove sections do not hinder the motion of the vibrating arm, which vibrates, when the detecting vibrating arm vibrates in the ±Z-axis directions in the out-of-plane vibration mode. Therefore, the structure easy for the detecting vibrating arm to vibrate is obtained, and thus, the detection sensitivity can be improved.

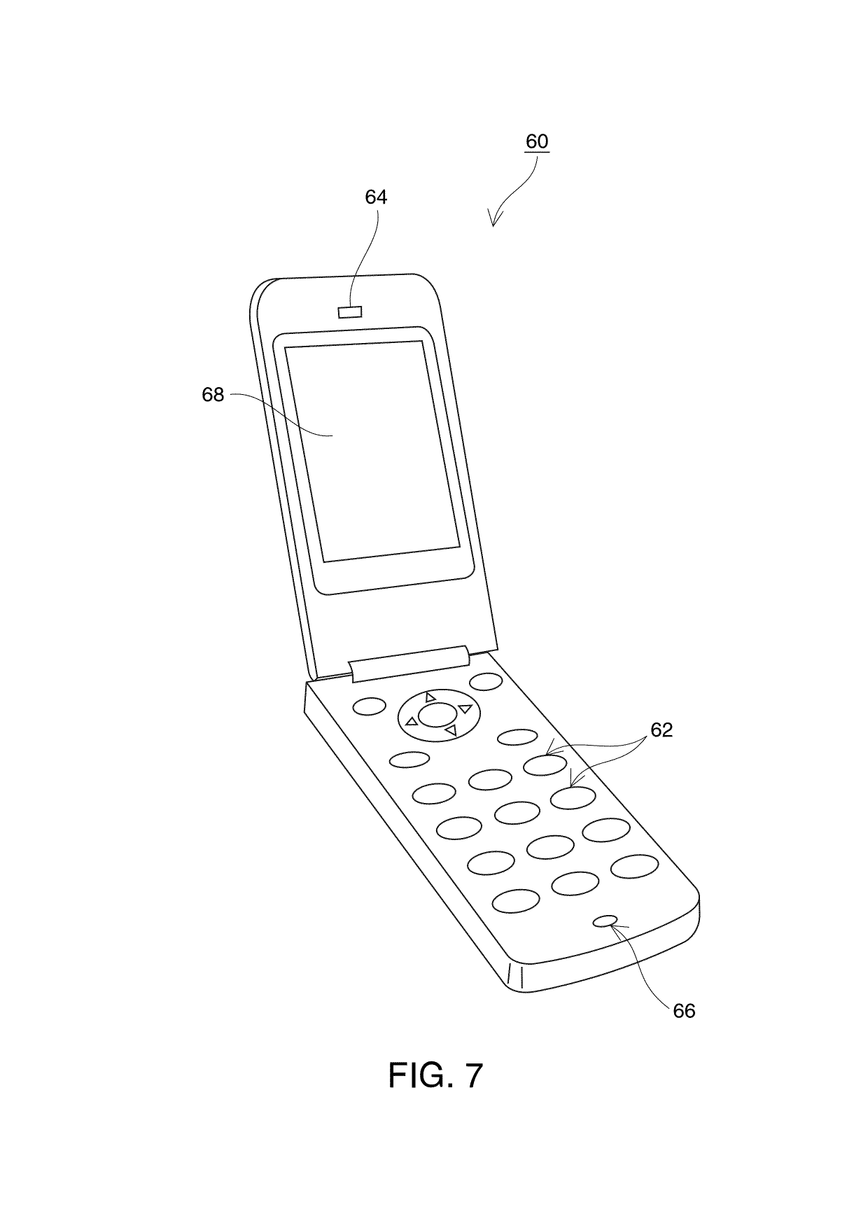

The vibrator element according to the embodiment of the invention constitutes a variety of types of sensor elements, and can be applied to a variety of electronic devices and electronic apparatuses. FIG. 7 is an explanatory diagram of an electronic apparatus using the vibrator element according to the embodiment of the invention. In FIG. 7, a portable terminal 60 (including PHS) is provided with a plurality of operation buttons 62, an ear piece 64, and a mouthpiece 66, and a display section 68 is disposed between the operation buttons 62 and the ear piece 64.

It should be noted that, the electronic apparatus equipped with the vibrator element according to the present embodiment includes a wide variety of electronic apparatuses such as a smartphone, a digital still camera, a personal computer, a tablet personal computer, a laptop personal computer, a television set, a video camera, a video cassette recorder, a car navigation system, a pager, an inkjet ejection device, a personal digital assistance, an electronic calculator, a computerized game machine, a word processor, a workstation, a video phone, a security video monitor, a pair of electronic binoculars, a POS terminal, a medical device (e.g., an electronic thermometer, an electronic manometer, an electronic blood sugar meter, an electrocardiogram measurement instrument, an ultrasonograph, and an electronic endoscope), a fish detector, various types of measurement instruments, various types of gauges (e.g., gauges for a vehicle, an aircraft, or a ship), and a flight simulator in addition to the portable terminal 60 described above.

The entire disclosure of Japanese Patent Application No. 2012-124137, filed May 31, 2012 is expressly incorporated by reference herein.

What is claimed is:

1. A vibrator element comprising:
a base section; and
a vibrating arm projecting from the base section, and having a plurality of groove sections,
wherein the groove sections are each formed to have a length in a width direction of the vibrating arm longer than a length in a longitudinal direction of the vibrating arm, and arranged side by side along the longitudinal direction of the vibrating arm.

2. The vibrator element according to claim 1, wherein
each of the groove sections has a polygonal shape in a plan view of the vibrating arm.

3. The vibrator element according to claim 1, wherein
a corner portion of each of the groove sections includes a curved shape in a plan view of the vibrating arm.

4. The vibrator element according to claim 1, wherein
the base section and the vibrating arm are formed of piezoelectric single crystal.

5. The vibrator element according to claim 2, wherein
the base section and the vibrating arm are formed of piezoelectric single crystal.

6. The vibrator element according to claim 3, wherein
the base section and the vibrating arm are formed of piezoelectric single crystal.

7. The vibrator element according to claim 1, wherein
the groove sections are formed on one principal surface and the other principal surface of the vibrating arm.

8. An electronic device comprising:
the vibrator element according to claim 1.

9. An electronic device comprising:
the vibrator element according to claim 2.

10. An electronic device comprising:
the vibrator element according to claim 3.

11. An electronic device comprising:
the vibrator element according to claim 4.

12. An electronic device comprising:
the vibrator element according to claim 5.

13. An electronic device comprising:
the vibrator element according to claim 6.

14. An electronic apparatus comprising:
the vibrator element according to claim 1.

15. An electronic apparatus comprising:
the vibrator element according to claim 2.

16. An electronic apparatus comprising:
the vibrator element according to claim 3.

17. An electronic apparatus comprising:
the vibrator element according to claim 4.

18. An electronic apparatus comprising:
the vibrator element according to claim 5.

19. An electronic apparatus comprising:
the vibrator element according to claim 6.

20. A method of manufacturing a vibrator element having a base section, and a vibrating arm formed so as to project from the base section and provided with a plurality of groove sections, the method comprising:
providing an outline pattern of the vibrator element and a pattern corresponding to the groove sections each formed to have a length in a width direction of the vibrating arm longer than a length in a longitudinal direction of the vibrating arm, and arranged side by side along the longitudinal direction of the vibrating arm simultaneously to a photoresist film on a metal film formed on a substrate;
removing the photoresist film and the metal film from an area corresponding to an outer shape of the vibrator element and areas corresponding to the groove sections; and
forming simultaneously the outer shape of the vibrator element and the groove sections by etching the substrate.
